(19) United States
(12) Patent Application Publication
(10) Pub. No.: US 2025/0012321 A1
(43) Pub. Date: Jan. 9, 2025

(54) LINEAR/CURVILINEAR GUIDING DEVICE

(71) Applicant: NIPPON THOMPSON CO., LTD., Tokyo (JP)

(72) Inventor: Satoshi SASAKI, Mino-shi (JP)

(73) Assignee: NIPPON THOMPSON CO., LTD., Tokyo (JP)

(21) Appl. No.: 18/711,745

(22) PCT Filed: Nov. 9, 2022
(86) PCT No.: PCT/JP2022/041664

§ 371 Date: May 20, 2024

(30) Foreign Application Priority Data
Nov. 26, 2021 (JP) 2021-191742

(51) Int. Cl. F16C 29/00; F16C 29/04

(52) U.S. Cl. CPC F16C 29/005; F16C 29/04

(57) ABSTRACT

A straight-curved guide device includes a rail and a movable element. The movable element includes a frame, a first swing portion, and a second swing portion. Each of the first swing portion and the second swing portion includes an arm portion, a first bearing portion, and a second bearing portion. The first bearing portion includes a first track member, a second track member, a third track member, a plurality of first rolling elements, and a plurality of second rolling elements. The second bearing portion includes a fourth track member, a fifth track member, and third rolling elements. The second track member of each of the first swing portion and the second swing portion is connected to the frame, and the second bearing portion of each of the first swing portion and the second swing portion is separate from the frame.

### TECHNICAL FIELD

The present disclosure relates to a straight-curved guide device. This application claims priority from Japanese Patent Application No. 2021-191742, filed on Nov. 26, 2021, the contents of which are incorporated herein by reference in their entirety.

### BACKGROUND ART

Hitherto, there has been known a straight-curved guide device in which a movable element travels on a circulation circuit formed by straight rails and curved rails. This kind of technology is disclosed in, for example, Patent Literature 1 and Patent Literature 2.

A straight-curved guide device disclosed in Patent Literature 1 includes a table, a pair of sliders, and carriages. The pair of sliders are arranged on a lower surface of the table. The carriages are arranged on the lower surface at a position between the pair of sliders. The carriage includes an arm, a pair of rollers, and a slewing bearing. The pair of rollers are arranged on two ends of the arm, respectively. The slewing bearing is arranged on the arm at a position between the pair of rollers. The slewing bearing includes an outer ring, a rotary shaft, an inner ring, and cylindrical rollers. The outer ring is fitted into a recessed portion formed in the lower surface of the table. The inner ring is fixed to an outer peripheral surface of the rotary shaft. The cylindrical rollers are arranged in a rolling passage between a raceway surface of the outer ring and a raceway surface of the inner ring. The pair of rollers are fixed to the arm through intermediation of shaft members. A nut is tightened to a distal end portion of each of the shaft members.

### CITATION LIST

### Patent Literature

[PTL 1] WO 2019/009105 A1
[PTL 2] U.S. Pat. No. 5,086,705 A

### SUMMARY OF INVENTION

### Technical Problem

In the straight-curved guide device disclosed in Patent Literature 1, the slewing bearing is arranged on the arm at a position between the pair of rollers and is mounted to the lower surface of the table. Thus, a space for the arrangement of the slewing bearing is required to be secured around the arm. Hence, there arises a problem in that a reduction in length of the arm is difficult to achieve.

An object of the present disclosure is to provide a straight-curved guide device that enables a reduction in length of an arm of a swing portion.

### Solution to Problem

A straight-curved guide device according to the present disclosure includes: a rail including a straight part and a curved part; and a movable element being movable on the rail. The movable element includes: a frame; a first swing portion, which is connected to the frame and is in contact with the rail; and a second swing portion, which is connected to the frame in such a manner as to be spaced apart from the first swing portion in a longitudinal direction of the rail and is in contact with the rail. Each of the first swing portion and the second swing portion includes: an arm portion extending in a width direction of the rail; a first bearing portion arranged on one side of the arm portion when viewed from a center of the arm portion in a longitudinal direction of the arm portion; and a second bearing portion arranged on another side of the arm portion when viewed from the center of the arm portion in the longitudinal direction of the arm portion. The first bearing portion includes a first track member, a second track member, a third track member, a plurality of first rolling elements, and a plurality of second rolling elements. The first track member passes through the arm portion in a height direction of the rail and is fixed to the arm portion. The first track member has an outer peripheral surface including a first raceway surface having a circular annular shape and a second raceway surface having a circular annular shape, which is arranged away from the first raceway surface in the height direction of the rail so that the arm portion is located between the first raceway surface and the second raceway surface. The second track member has a circular annular shape, has an inner peripheral surface including a third raceway surface having a circular annular shape being opposed to the first raceway surface, and is connected to the frame. The third track member has an inner peripheral surface including a fourth raceway surface having a circular annular shape being opposed to the second raceway surface and has an outer peripheral surface including a first rail groove having a circular annular shape being in contact with the rail. The first rolling elements are arranged in a first rolling passage having a circular annular shape defined by the first raceway surface and the third raceway surface. The second rolling elements are arranged in a second rolling passage having a circular annular shape defined by the second raceway surface and the fourth raceway surface. The second bearing portion includes a fourth track member, a fifth track member, and third rolling elements. The fourth track member has an outer peripheral surface including a fifth raceway surface having a circular annular shape and is fixed to the arm portion. The fifth track member has an inner peripheral surface including a sixth raceway surface opposed to the fifth raceway surface and has an outer peripheral surface including a second rail groove having a circular annular shape being in contact with the rail. The third rolling elements are arranged in a third rolling passage having a circular annular shape defined by the fifth raceway surface and the sixth raceway surface. The second track member of each of the first swing portion and the second swing portion is connected to the frame, and the second bearing portion of each of the first swing portion and the second swing portion is separate from the frame.

### Advantageous Effects of Invention

According to the present disclosure, the straight-curved guide device that enables a reduction in length of the arm of the swing portion can be provided.

### BRIEF DESCRIPTION OF DRAWINGS

FIG. 1 is a perspective view for illustrating a configuration of a straight-curved guide device according to a first embodiment.

FIG. 2 is a front view for illustrating the configuration of the straight-curved guide device according to the first embodiment.

FIG. 3 is a plan view for illustrating the straight-curved guide device according to the first embodiment with a magnet yoke removed.

FIG. 4 is a perspective view for generally illustrating a configuration of a first swing portion of the straight-curved guide device according to the first embodiment.

FIG. 5 is a sectional view of the first swing portion, taken along the line V-V of FIG. 4.

FIG. 6 is a perspective view for illustrating a configuration of a straight-curved guide device according to a second embodiment.

FIG. 7 is a front view for illustrating the configuration of the straight-curved guide device according to the second embodiment.

FIG. 8 is a plan view of the straight-curved guide device according to the second embodiment with a magnet yoke removed.

### DESCRIPTION OF EMBODIMENTS

### Outline of Embodiments

A straight-curved guide device according to the present disclosure includes: a rail including a straight part and a curved part; and a movable element being movable on the rail. The movable element includes: a frame; a first swing portion, which is connected to the frame and is in contact with the rail; and a second swing portion, which is connected to the frame in such a manner as to be spaced apart from the first swing portion in a longitudinal direction of the rail and is in contact with the rail. Each of the first swing portion and the second swing portion includes: an arm portion extending in a width direction of the rail; a first bearing portion arranged on one side of the arm portion when viewed from a center of the arm portion in a longitudinal direction of the arm portion; and a second bearing portion arranged on another side of the arm portion when viewed from the center of the arm portion in the longitudinal direction of the arm portion. The first bearing portion includes a first track member, a second track member, a third track member, a plurality of first rolling elements, and a plurality of second rolling elements. The first track member passes through the arm portion in a height direction of the rail and is fixed to the arm portion. The first track member has an outer peripheral surface including a first raceway surface having a circular annular shape and a second raceway surface having a circular annular shape, which is arranged away from the first raceway surface in the height direction of the rail so that the arm portion is located between the first raceway surface and the second raceway surface. The second track member has a circular annular shape, has an inner peripheral surface including a third raceway surface having a circular annular shape being opposed to the first raceway surface, and is connected to the frame. The third track member has an inner peripheral surface including a fourth raceway surface having a circular annular shape being opposed to the second raceway surface and has an outer peripheral surface including a first rail groove having a circular annular shape being in contact with the rail. The first rolling elements are arranged in a first rolling passage having a circular annular shape defined by the first raceway surface and the third raceway surface. The second rolling elements are arranged in a second rolling passage having a circular annular shape defined by the second raceway surface and the fourth raceway surface. The second bearing portion includes a fourth track member, a fifth track member, and third rolling elements. The fourth track member has an outer peripheral surface including a fifth raceway surface having a circular annular shape and is fixed to the arm portion. The fifth track member has an inner peripheral surface including a sixth raceway surface opposed to the fifth raceway surface and has an outer peripheral surface including a second rail groove having a circular annular shape being in contact with the rail. The third rolling elements are arranged in a third rolling passage having a circular annular shape defined by the fifth raceway surface and the sixth raceway surface. The second track member of each of the first swing portion and the second swing portion is connected to the frame, and the second bearing portion of each of the first swing portion and the second swing portion is separate from the frame.

In the straight-curved guide device, the second track member of the first bearing portion arranged on the one side of the arm portion when viewed from the center of the arm portion in the longitudinal direction of the arm portion is connected to the frame. As a result, each of the first swing portion and the second swing portion is supported by the frame in a cantilever fashion. Thus, unlike a related-art straight-curved guide device, a space for arrangement of a slewing bearing between the first bearing portion and the second bearing portion on the arm portion is not required to be secured. Hence, with the straight-curved guide device, the arm of each of the swing portions can be reduced in length.

In the straight-curved guide device, the first track member may include: a shaft member passing through the arm portion in the height direction of the rail; and an annular member surrounding an outer peripheral surface of the shaft member. A first thread portion may be formed on the outer peripheral surface of the shaft member. A second thread portion to be meshed with the first thread portion may be formed on an inner peripheral surface of the annular member. The first raceway surface may be formed on an outer peripheral surface of the annular member. With the configuration described above, the shaft member and the annular member can easily be mounted.

In the straight-curved guide device, the frame may have an insertion hole into which the second track member is inserted. The second track member may have an outer peripheral surface being in contact with an entire wall surface of the insertion hole in a circumferential direction. With the configuration described above, the first swing portion and the second swing portion can be more stably mounted to the frame.

In the straight-curved guide device, the second track member may have a feed port for feeding the first rolling elements into the first rolling passage, which is formed so as to pass through the second track member in a radial direction of the second track member. The second track member may include a lid member configured to close the feed port. The lid member may have a lid raceway surface being in contact with the first rolling elements and a lid outer surface being located on a side opposite to the lid raceway surface in the radial direction of the second track member. The lid outer surface may be in contact with the wall surface of the insertion hole. With the configuration described above, shifting of a position of the lid member in the radial direction can be suppressed to thereby enable the lid raceway surface and the third raceway surface to be maintained flush or substantially flush with each other.

The straight-curved guide device may further include fixing members configured to fix each of the first swing portion and the second swing portion to the frame. The frame may have first fixing holes into which the fixing members are inserted. The second track member may have second fixing holes, which communicate with the first fixing holes and into which the fixing members are inserted. With the configuration described above, each of the first swing portion and the second swing portion can be more reliably mounted to the frame with the fixing members.

In the straight-curved guide device, the fourth track member may pass through the arm portion in the height direction of the rail. The second bearing portion may further include an eccentric collar having a circular annular shape, which is inserted between a wall surface of a through hole of the arm portion, through which the fourth track member passes, and an outer peripheral surface of the fourth track member. The eccentric collar may have a shape with a radial thickness changing in a circumferential direction. With the configuration described above, when the eccentric collar is rotated in the circumferential direction, a distance between the first rail groove and the second rail groove can be adjusted.

### Description of Specific Embodiments

Next, specific embodiments of a straight-curved guide device according to the present disclosure are described with reference to the drawings. In the drawings referred to below, the same or corresponding portions are denoted by the same reference symbols, and a description thereof is not repeated.

### First Embodiment

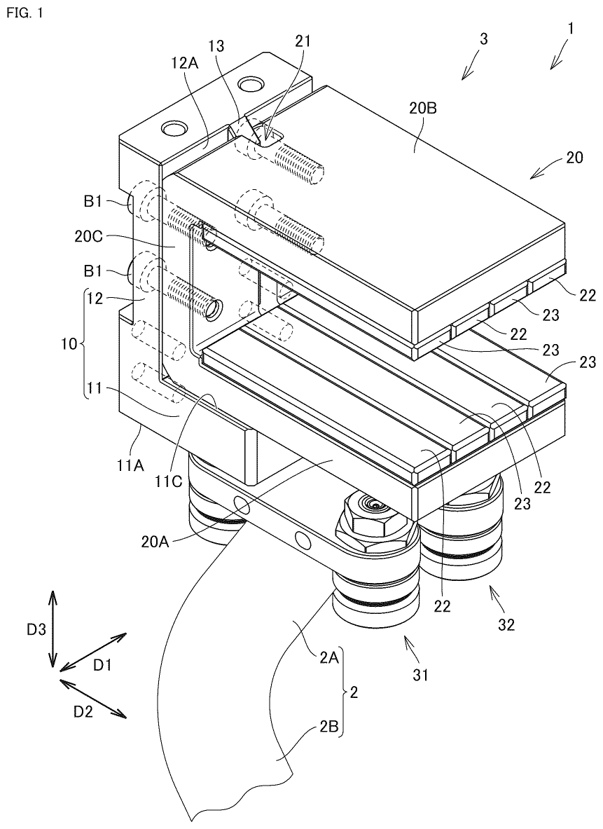

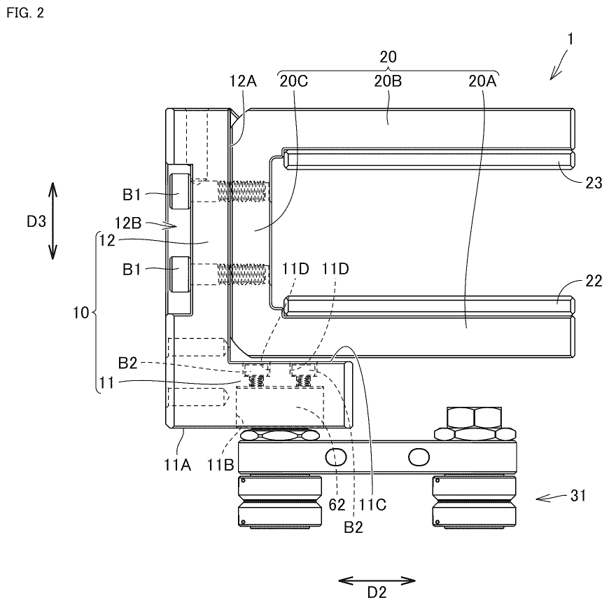

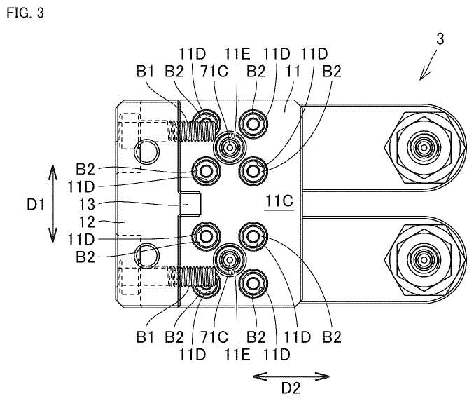

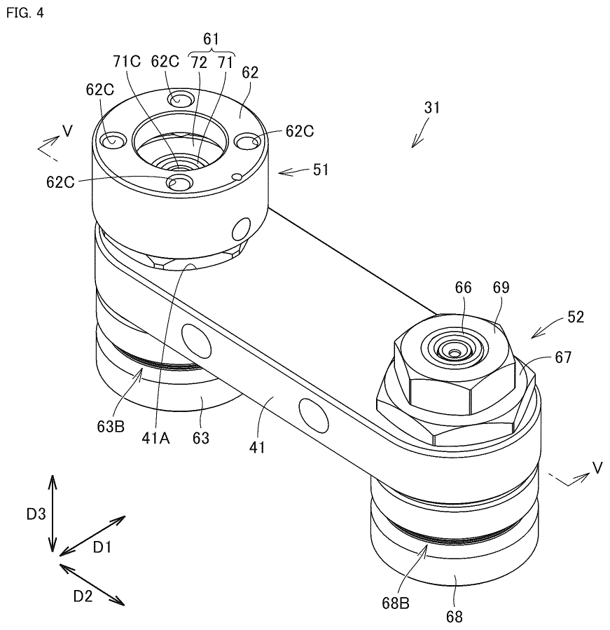

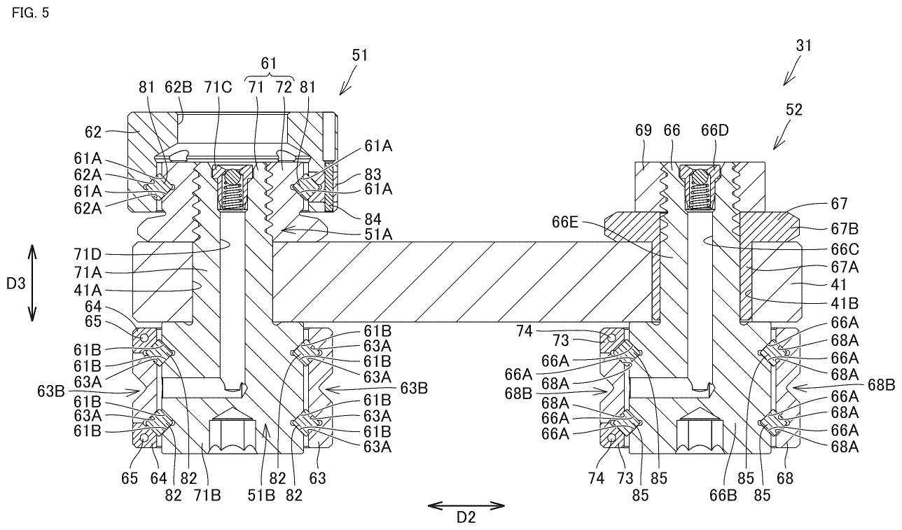

First, a configuration of a straight-curved guide device 1 according to a first embodiment is described with reference to FIG. 1 to FIG. 5. FIG. 1 is a perspective view for illustrating the configuration of the straight-curved guide device 1. FIG. 2 is a front view for illustrating the configuration of the straight-curved guide device 1. FIG. 3 is a plan view of the straight-curved guide device 1 with a magnet yoke 20 removed. FIG. 4 is a perspective view for generally illustrating a configuration of a first swing portion 31. FIG. 5 is a sectional view of the first swing portion 31, taken along the line V-V of FIG. 4.

As illustrated in FIG. 1, the straight-curved guide device 1 includes a rail 2 and a movable element 3 as main components. The movable element 3 is movable on the rail 2. The rail 2 includes a straight part 2A and a curved part 2B connected to an end portion of the straight part 2A. The movable element 3 includes a frame 10, the magnet yoke 20, the first swing portion 31, and a second swing portion 32 as main components. Now, each of those components is described. A longitudinal direction D1, a width direction D2, and a height direction D3 of the rail 2 in this specification conform to those illustrated in FIG. 1 to FIG. 5.

As illustrated in FIG. 1, the frame 10 includes a first frame part 11 and a second frame part 12. Each of the first frame part 11 and the second frame part 12 in this embodiment has a quadrangular plate shape. The second frame part 12 extends perpendicularly to the first frame part 11 from an end portion of the first frame part 11 in the width direction D2.

The first frame part 11 has a first surface 11A (lower surface) and a second surface 11C (upper surface). The first surface 11A faces downward in the height direction D3. The second surface 11C faces in a direction (upward in the height direction D3, toward the magnet yoke 20) opposite to the direction in which the first surface 11A faces. The second frame part 12 has a third surface 12A. The third surface 12A is a surface that is perpendicular to the second surface 11C and faces toward the magnet yoke 20. As illustrated in FIG. 1, a first protruding portion 13 is formed on a substantially center area of the third surface 12A in the longitudinal direction D1. The first protruding portion 13 protrudes in the width direction D2 and extends in the height direction D3.

The magnet yoke 20 has a shape that opens in a direction opposite to the third surface 12A. More specifically, as illustrated in FIG. 1, the magnet yoke 20 includes a first yoke portion 20A, a second yoke portion 20B, and a third yoke portion 20C. The first yoke portion 20A is arranged on the second surface 11C. The second yoke portion 20B is spaced apart from and opposed to the first yoke portion 20A in the height direction D3. The third yoke portion 20C connects an end portion of the first yoke portion 20A in the width direction D2 and an end portion of the second yoke portion 20B in the width direction D2 to each other. A recessed portion 21 into which the first protruding portion 13 is inserted is formed in the third yoke portion 20C in such a manner as to extend in the height direction D3.

As illustrated in FIG. 1, first magnets 22 and second magnets 23 are arranged alternately in the longitudinal direction D1 on an inner surface (surface opposed to the second yoke portion 20B) of the first yoke portion 20A. First magnets 22 and second magnets 23 are arranged alternately in the longitudinal direction D1 on an inner surface (surface opposed to the first yoke portion 20A) of the second yoke portion 20B. As illustrated in FIG. 1, the first magnets 22 arranged on the inner surface of the first yoke portion 20A are opposed to the second magnets 23 arranged on the inner surface of the second yoke portion 20B in the height direction D3. Meanwhile, the second magnets 23 arranged on the inner surface of the first yoke portion 20A are opposed to the first magnets 22 arranged on the inner surface of the second yoke portion 20B in the height direction D3.

As illustrated in FIG. 2, the magnet yoke 20 is fixed to the frame 10 (second frame part 12) with a plurality of first bolts B1. Specifically, bolt holes are formed in the second frame part 12 and in the third yoke portion 20C and communicate with each other in the width direction D2. Female thread portions, which are to be meshed with male thread portions of the first bolts B1, are formed on wall surfaces of the bolt holes of the third yoke portion 20C, respectively.

When the first bolts B1 are inserted into the bolt holes, the magnet yoke 20 is fixed to the frame 10. As illustrated in FIG. 2, a recessed portion 12B is formed in an outer surface (surface opposite to the third surface 12A) of the second frame part 12. Head portions of the first bolts B1 are accommodated in the recessed portion 12B. A plurality of (eight in this embodiment) first fixing holes 11D are formed in the first frame part 11 in such a manner as to open toward the second surface 11C. Second bolts B2 (fixing members) are inserted into the first fixing holes 11D. The second bolts B2 are provided in order to fix each of the first swing portion 31 and the second swing portion 32 to the frame 10 (first frame part 11).

The first swing portion 31 is a portion being in contact with the rail 2. As illustrated in FIG. 1, the first swing portion 31 is connected to the first frame part 11. More specifically, as illustrated in FIG. 2, an insertion hole 11B is formed in the first frame part 11. The insertion hole 11B opens toward the first surface 11A and has a predetermined depth in the height direction D3. The insertion hole 11B has a circular shape when viewed in the height direction D3. When a part (second track member 62 described later) of the first swing portion 31 is inserted into the insertion hole 11B and the second bolts B2 are tightened, the first swing portion 31 is connected to the first surface 11A of the first frame part 11. As illustrated in FIG. 2, a distal end portion (portion opposite to the portion connected to the frame 10) of the first swing portion 31 is located in front of a distal end portion of the first frame part 11 (located on a side closer to an opening of the magnet yoke 20).

As illustrated in FIG. 3, a plurality of (two in this embodiment) oil supply holes 11E are formed in the first frame part 11. The oil supply hole 11E communicates with the insertion hole 11B (FIG. 2) in the height direction D3. Each of the oil supply holes 11E has a circular shape that is concentric with the insertion hole 11B (FIG. 2) and has a diameter smaller than that of the insertion hole 11B when viewed in the height direction D3. As illustrated in FIG. 3, a plurality of (four in this embodiment) first fixing holes 11D are formed in such a manner as to surround each of the oil supply holes 11E when viewed in the height direction D3.

Similarly to the first swing portion 31, the second swing portion 32 is a portion being in contact with the rail 2. As illustrated in FIG. 1, the second swing portion 32 is spaced apart from the first swing portion 31 in the longitudinal direction D1 and is connected to the frame 10 (first frame part 11). The second swing portion 32 is connected to the frame 10 in a manner similar to that of the first swing portion 31. Thus, a description of a mounting structure for the second swing portion 32 to the frame 10 is omitted.

Next, a configuration of the first swing portion 31 is described in detail with reference to FIG. 4 and FIG. 5. As illustrated in FIG. 4 and FIG. 5, the first swing portion 31 includes an arm portion 41, a first bearing portion 51, and a second bearing portion 52. The arm portion 41 extends in the width direction D2. The first bearing portion 51 is arranged on one side (one end portion of the arm portion 41 in a longitudinal direction of the arm portion 41) when viewed from a center of the arm portion 41 in the longitudinal direction (width direction D2 of the rail 2). The second bearing portion 52 is arranged on another side (another end portion of the arm portion 41 in the longitudinal direction of the arm portion 41) when viewed from the center of the arm portion 41 in the longitudinal direction. As illustrated in FIG. 5, a first through hole 41A passing through the arm portion 41 in the height direction D3 is formed on the one side when viewed from the center of the arm portion 41 in the longitudinal direction. Meanwhile, a second through hole 41B passing through the arm portion 41 in the height direction D3 is formed on the another side when viewed from the center of the arm portion 41 in the longitudinal direction.

As illustrated in FIG. 5, the first bearing portion 51 includes a first track member 61, the second track member 62, and a third track member 63. The first track member 61 has a first end portion 51A and a second end portion 51B. The second end portion 51B is opposite to the first end portion 51A in the height direction D3. The first track member 61 passes through the arm portion 41 in the height direction D3 and is fixed to the arm portion 41. Specifically, the first track member 61 in this embodiment includes a first stud 71 (shaft member) and a first nut 72 (annular member). The first stud 71 passes through the arm portion 41 (is inserted into the first through hole 41A) in the height direction D3. The first nut 72 has a circular annular shape and surrounds an outer peripheral surface of the first stud 71.

The first stud 71 includes a shaft portion 71A and a head portion 71B. The shaft portion 71A has a columnar shape and is inserted into the first through hole 41A. The head portion 71B has a diameter larger than that of the shaft portion 71A and is connected to a lower end portion of the shaft portion 71A. As illustrated in FIG. 5, an outer peripheral surface of the shaft portion 71A is in contact with an entire wall surface of the first through hole 41A in its circumferential direction. A first thread portion (male thread portion) is formed on an outer peripheral surface of a distal end portion (portion opposite to the head portion 71B) of the shaft portion 71A. A second thread portion (female thread portion) to be meshed with the first thread portion is formed on an entire inner peripheral surface of the first nut 72 in its circumferential direction.

As illustrated in FIG. 5, a first oil supply passage 71D is defined inside the first stud 71. The first oil supply passage 71D includes a first passage portion and a second passage portion. The first passage portion extends in the height direction D3 inside the shaft portion 71A. The second passage portion is connected to a lower end portion of the first passage portion and extends in a radial direction inside the head portion 71B. A first grease nipple 71C is arranged at an inlet of the first oil supply passage 71D. Lubricating oil can be supplied to a gap between the head portion 71B of the first stud 71 and the third track member 63 via the first oil supply passage 71D.

The first track member 61 has an outer peripheral surface including a first raceway surface 61A having a circular annular shape and second raceway surfaces 61B, each having a circular annular shape. The second raceway surfaces 61B are arranged away from the first raceway surface 61A in the height direction D3 so that the arm portion 41 is located between the first raceway surface 61A and the second raceway surfaces 61B. As illustrated in FIG. 5, in this embodiment, the first raceway surface 61A is formed on an outer peripheral surface of the first nut 72. The first raceway surface 61A defines a V-shaped groove in cross section taken in the height direction D3.

In this embodiment, the second raceway surfaces 61B are formed on an outer peripheral surface of the first stud 71 (head portion 71B). As illustrated in FIG. 5, the second raceway surfaces 61B each define a V-shaped groove in cross section taken in the height direction D3. In this embodiment, a plurality of (two) rows of the second raceway surfaces 61B are formed spaced apart from each other in the height direction D3. However, the second raceway surfaces 61B are not limited to those described above. The second raceway surface 61B may be formed in a single row.

The second track member 62 (outer ring) is a circular annular member having an inner diameter larger than that of the first raceway surface 61A. The second track member 62 has an inner peripheral surface including a third raceway surface 62A. The third raceway surface 62A has a circular annular shape and is opposed to the first raceway surface 61A in a radial direction of the second track member 62. As illustrated in FIG. 5, the third raceway surface 62A is formed symmetrically to the first raceway surface 61A in cross section taken in the height direction D3. An annular hole 62B is formed in the second track member 62. The annular hole 62B overlaps the inlet of the first oil supply passage 71D in the height direction D3. The annular hole 62B overlaps the oil supply hole 11E (FIG. 3) in the height direction D3.

The second track member 62 is connected to the frame 10 (first frame part 11). Specifically, as illustrated in FIG. 2, the second track member 62 is inserted into the insertion hole 11B and is fixed to the first frame part 11 with the plurality of second bolts B2. An outer peripheral surface of the second track member 62 is in contact with an entire wall surface of the insertion hole 11B in its circumferential direction. As illustrated in FIG. 2, a lower end surface of the second track member 62 in the height direction D3 is substantially flush with the first surface 11A of the frame 10.

As illustrated in FIG. 4, second fixing holes 62C are formed in the second track member 62. The second fixing holes 62C communicate with the first fixing holes 11D (FIG. 2), and the second bolts B2 (FIG. 2) are inserted into the second fixing holes 62C. A plurality of (four in this embodiment) second fixing holes 62C are formed equiangularly in an end surface of the second track member 62. A female thread portion (not shown) to be meshed with a male thread portion of the second bolt B2 (FIG. 2) is formed on an entire wall surface of the second fixing hole 62C in its circumferential direction.

The third track member 63 is a circular annular member having an inner diameter larger than that of the second raceway surface 61B. The third track member 63 has an inner peripheral surface including fourth raceway surfaces 63A. The fourth raceway surfaces 63A have a circular annular shape and are opposed to the second raceway surfaces 61B in a radial direction of the third track member 63. As illustrated in FIG. 5, the third track member 63 has an outer peripheral surface including a first rail groove 63B formed therein. The first rail groove 63B has a circular annular shape and is in contact with the rail 2. The first rail groove 63B in this embodiment is a V-shaped groove in cross section taken in the height direction D3. However, the first rail groove 63B is not limited to that described above.

The first bearing portion 51 further includes a plurality of first rolling elements 81 arranged in a first rolling passage having a circular annular shape. The first rolling passage is defined by the first raceway surface 61A and the third raceway surface 62A. The first rolling elements 81 in this embodiment are cylindrical rollers and are in contact with the first raceway surface 61A and the third raceway surface 62A.

As illustrated in FIG. 5, a feed port for feeding the first rolling elements 81 into the first rolling passage is formed in the second track member 62 in such a manner as to radially pass through a part of the second track member 62 in its circumferential direction. The feed port is closed with a first lid member 83. The first lid member 83 has a lid raceway surface (surface opposed to the first raceway surface 61A in the radial direction of the second track member 62) and a lid outer surface. The lid raceway surface is in contact with the first rolling elements 81. The lid outer surface is located on a side opposite to the lid raceway surface in the radial direction of the second track member 62. The lid raceway surface is substantially flush with the third raceway surface 62A and defines the first rolling passage in cooperation with the first raceway surface 61A and the third raceway surface 62A. The lid outer surface is in contact with the wall surface of the insertion hole 11B under a state in which the second track member 62 is located in the insertion hole 11B after being inserted thereinto. As illustrated in FIG. 5, the first lid member 83 is fixed to the second track member 62 with a pin 84 extending in the height direction D3.

The first bearing portion 51 further includes a plurality of second rolling elements 82 arranged in a second rolling passage having a circular annular shape. The second rolling passage is defined by the second raceway surface 61B and the fourth raceway surface 63A. The second rolling elements 82 in this embodiment are cylindrical rollers and are in contact with the second raceway surface 61B and the fourth raceway surface 63A. As illustrated in FIG. 5, a feed port for feeding the second rolling elements 82 into the second rolling passage is formed in the third track member 63. A second lid member 64 is arranged at the feed port. The second lid member 64 is fixed to the third track member 63 with a pin 65.

As illustrated in FIG. 5, the second bearing portion 52 includes a fourth track member 66, a fifth track member 68, an eccentric collar 67, a second nut 69, and third rolling elements 85. The fourth track member 66 passes through the arm portion 41 in the height direction D3 and is fixed to the arm portion 41. Specifically, the fourth track member 66 is a stud (second stud) including a shaft portion 66E and a head portion 66B. The shaft portion 66E is inserted into the second through hole 41B of the arm portion 41. The head portion 66B has a diameter larger than that of the shaft portion 66E and is connected to a lower end portion of the shaft portion 66E. As illustrated in FIG. 5, a second oil supply passage 66C for supplying lubricating oil to the third rolling elements 85 is defined inside the fourth track member 66. A second grease nipple 66D is arranged at an inlet of the second oil supply passage 66C.

A third thread portion (male thread portion) is formed on an outer peripheral surface of a distal end portion (portion opposite to the head portion 66B) of the shaft portion 66E. The second nut 69 has a circular annular shape that surrounds the outer peripheral surface of the shaft portion 66E. A fourth thread portion (female thread portion) to be meshed with the third thread portion is formed on an entire inner peripheral surface of the second nut 69 in its circumferential direction. As illustrated in FIG. 5, the eccentric collar 67 includes a small-diameter portion 67A and a flange portion 67B. The small-diameter portion 67A has a circular annular shape and is inserted into a gap between the outer peripheral surface of the shaft portion 66E and a wall surface of the second through hole 41B. The flange portion 67B extends radially outward from an end portion of the small-diameter portion 67A. The eccentric collar 67 has a shape with a radial thickness changing in its circumferential direction.

The fourth track member 66 (head portion 66B) has an outer peripheral surface including fifth raceway surfaces 66A having a circular annular shape. As illustrated in FIG. 5, the fifth raceway surfaces 66A each define a V-shaped groove in cross section taken in the height direction D3. In this embodiment, a plurality of (two) rows of the fifth raceway surfaces 66A are formed spaced apart from each other in the height direction D3. However, the fifth raceway surfaces 66A are not limited to those described above.

The fifth track member 68 is a circular annular member having an inner diameter larger than that of the fifth raceway surface 66A. The fifth track member 68 has an inner peripheral surface including sixth raceway surfaces 68A. The sixth raceway surfaces 68A are opposed to the fifth raceway surfaces 66A in a radial direction of the fifth track member 68. As illustrated in FIG. 5, the fifth track member 68 has an outer peripheral surface including a second rail groove 68B formed therein.

A plurality of third rolling elements 85 are arranged in a third rolling passage having a circular annular shape. The third rolling passage is defined by the fifth raceway surface 66A and the sixth raceway surface 68A. The third rolling elements 85 in this embodiment are cylindrical rollers and are in contact with the fifth raceway surface 66A and the sixth raceway surface 68A. As illustrated in FIG. 5, a feed port for feeding the third rolling elements 85 into the third rolling passage is formed in the fifth track member 68. A third lid member 73 is arranged at the feed port. The third lid member 73 is fixed to the fifth track member 68 with a pin 74.

The second swing portion 32 (FIG. 1) basically has a configuration similar to that of the first swing portion 31. The second swing portion 32 is connected to the frame 10 (first frame part 11) in a manner similar to that of the first swing portion 31. Specifically, the second track member 62 of each of the first swing portion 31 and the second swing portion 32 is connected to the frame 10, and the second bearing portion 52 of each of the first swing portion 31 and the second swing portion 32 is separate from the frame 10 in the width direction D2. In other words, each of the first swing portion 31 and the second swing portion 32 is supported in a cantilever fashion by the frame 10 (first frame part 10) and is pivotable about a connecting portion to the frame 10 in an imaginary plane being parallel to the first surface 11A. A detailed description about the second swing portion 32 is omitted.

As described above, in the straight-curved guide device 1 according to this embodiment, the second track member 62 of the first bearing portion 51 arranged on the one side of the arm portion 41 when viewed from the center of the arm portion 41 in the longitudinal direction of the arm portion 41 is connected to the frame 10. As a result, each of the first swing portion 31 and the second swing portion 32 is supported by the frame 10 in a cantilever fashion. Thus, in the straight-curved guide device 1, a space for arrangement of a slewing bearing between the first bearing portion 51 and the second bearing portion 52 on the arm portion 41 is not required to be secured. Hence, with the straight-curved guide device 1, the arm of each of the swing portions can be reduced in length.

### Second Embodiment

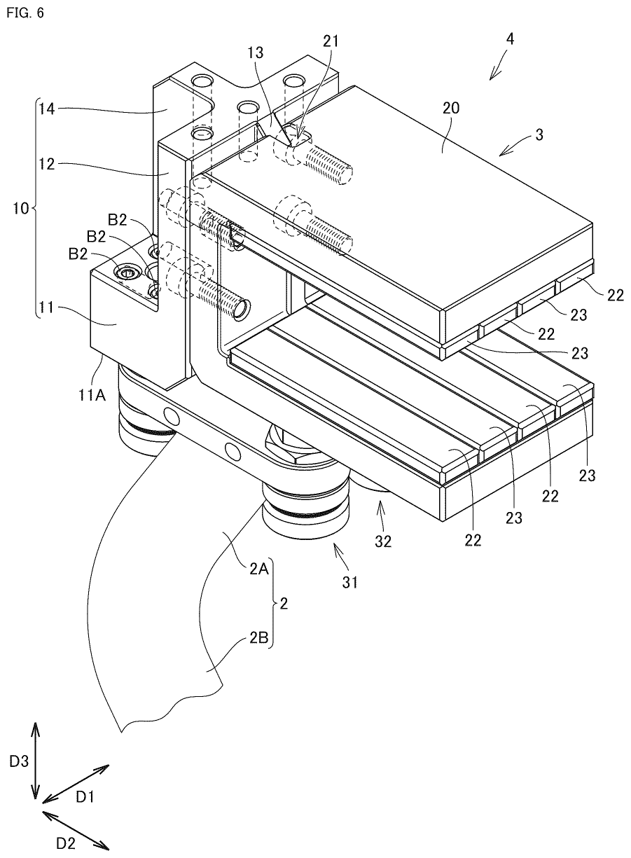

Next, a configuration of a straight-curved guide device 4 according to a second embodiment is described with reference to FIG. 6 to FIG. 8. The straight-curved guide device 4 according to the second embodiment basically has a configuration and effects similar to those of the straight-curved guide device 1 according to the first embodiment. However, the straight-curved guide device 4 differs from the straight-curved guide device 1 in shape of a frame 10. Differences from the first embodiment are mainly described below.

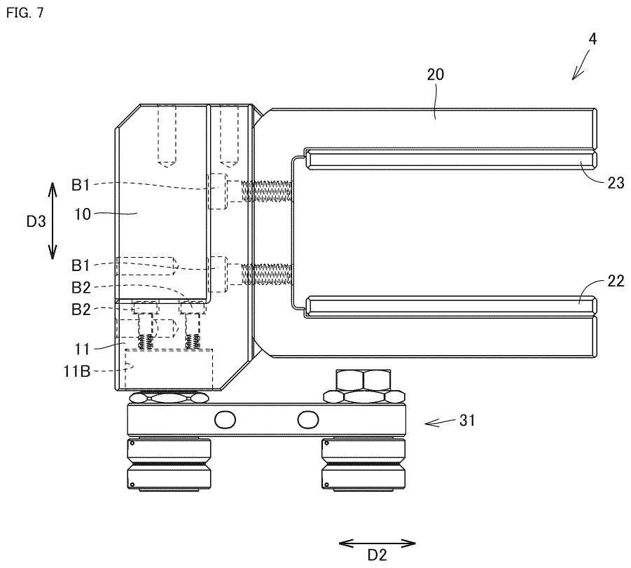

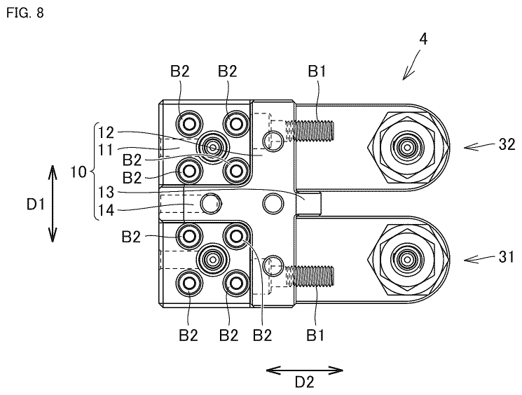

FIG. 6 is a perspective view for illustrating the configuration of the straight-curved guide device 4. FIG. 7 is a front view for illustrating the configuration of the straight-curved guide device 4. FIG. 8 is a plan view of the straight-curved guide device 4 with a magnet yoke 20 removed.

As illustrated in FIG. 6, the frame 10 in the second embodiment includes a second protruding portion 14 in addition to a first frame part 11, a second frame part 12, and a first protruding portion 13. The second protruding portion 14 is formed on a surface of the second frame part 12, which is opposite to a surface on which the first protruding portion 13 is formed. As illustrated in FIG. 6, the second protruding portion 14 protrudes in a direction opposite to the direction in which the first protruding portion 13 protrudes in the width direction D2, and extends in the height direction D3.

### Other Embodiments

Now, other embodiments are described.

In the first embodiment, the first track member 61 including two members, that is, the first stud 71 and the first nut 72, has been described as one example. However, the first track member 61 is not limited to that described above. The first track member may be formed of a single member.

In the first embodiment, the second track member 62 inserted into the insertion hole 11B has been described as one example. However, the second track member 62 is not limited to that described above. For example, bolts (not shown) may be provided so as to protrude downward in the height direction D3 from the first surface 11A, and may be inserted into the second fixing holes 62C (FIG. 4).

In the first embodiment, the fixing of the second track member 62 to the frame 10 with the second bolts B2 has been described as one example. However, a way of fixing the second track member 62 is not limited to that described above. For example, the second track member 62 may be press-fitted into the insertion hole 11B.

In the first embodiment, the second bearing portion 52 including the eccentric collar 67 has been described as one example. However, the eccentric collar 67 may be omitted.

It is to be understood that each of the embodiments disclosed herein is merely an example in all aspects and in no way intended to limit the present disclosure. The scope of the present invention is defined by the appended claims and not by the above description, and it is intended that the present invention encompasses all modifications made within the scope and spirit equivalent to those of the appended claims.

### REFERENCE SIGNS LIST

1,4 straight-curved guide device, 2 rail, 2A straight part, 2B curved part, 3 movable element, 10 frame, 11 first frame part, 11A first surface, 11B insertion hole, 11C second surface, 11D first fixing hole, 11E oil supply hole, 12 second frame part, 12A third surface, 12B recessed portion, 13 first protruding portion, 14 second protruding portion, 20 magnet yoke, 20A first yoke portion, 20B second yoke portion, 20C third yoke portion, 21 recessed portion, 22 first magnet, 23 second magnet, 31 first swing portion, 32 second swing portion, 41 arm portion, 41A first through hole, 41B second through hole, 51 first bearing portion, 51A first end portion, 51B second end portion, 52 second bearing portion, 61 first track member, 61A first raceway surface, 61B second raceway surface, 62 second track member, 62A third raceway surface, 62B annular hole, 62C second fixing hole, 63 third track member, 63A fourth raceway surface, 63B first rail groove, 64 second lid member, 65, 74, 84 pin, 66 fourth track member, 66A fifth raceway surface, 66B head portion, 66C second oil supply passage, 66D second grease nipple, 66E shaft portion, 67 eccentric collar, 67A small-diameter portion, 67B flange portion, 68 fifth track member, 68A sixth raceway surface, 68B second rail groove, 69 second nut, 71 first stud, 71A shaft portion, 71B head portion, 71C first grease nipple, 71D first oil supply passage, 72 first nut, 73 third lid member, 81 first rolling element, 82 second rolling element, 83 first lid member, 85 third rolling element, B1 first bolt, B2 second bolt, D1 longitudinal direction, D2 width direction, D3 height direction

1. A straight-curved guide device, comprising:
a rail including a straight part and a curved part; and
a movable element being movable on the rail, the movable element comprising:
a frame;
a first swing portion, which is connected to the frame and is in contact with the rail; and
a second swing portion, which is connected to the frame in such a manner as to be spaced apart from the first swing portion in a longitudinal direction of the rail and is in contact with the rail,
wherein each of the first swing portion and the second swing portion includes:
an arm portion extending in a width direction of the rail;
a first bearing portion arranged on one side of the arm portion when viewed from a center of the arm portion in a longitudinal direction of the arm portion; and
a second bearing portion arranged on another side of the arm portion when viewed from the center of the arm portion in the longitudinal direction of the arm portion,
wherein the first bearing portion includes:
a first track member, which passes through the arm portion in a height direction of the rail and is fixed to the arm portion, the first track member having an outer peripheral surface including a first raceway surface having a circular annular shape and a second raceway surface having a circular annular shape arranged away from the first raceway surface in the height direction of the rail so that the arm portion is located between the first raceway surface and the second raceway surface;
a second track member having a circular annular shape, which has an inner peripheral surface including a third raceway surface having a circular annular shape being opposed to the first raceway surface and is connected to the frame;
a third track member, which has an inner peripheral surface including a fourth raceway surface having a circular annular shape being opposed to the second raceway surface and has an outer peripheral surface including a first rail groove having a circular annular shape being in contact with the rail;
a plurality of first rolling elements arranged in a first rolling passage having a circular annular shape defined by the first raceway surface and the third raceway surface; and
a plurality of second rolling elements arranged in a second rolling passage having a circular annular shape defined by the second raceway surface and the fourth raceway surface,
wherein the second bearing portion includes:
a fourth track member, which has an outer peripheral surface including a fifth raceway surface having a circular annular shape and is fixed to the arm portion;
a fifth track member, which has an inner peripheral surface including a sixth raceway surface being opposed to the fifth raceway surface and has an outer peripheral surface including a second rail groove having a circular annular shape being in contact with the rail; and
third rolling elements arranged in a third rolling passage having a circular annular shape defined by the fifth raceway surface and the sixth raceway surface, and
wherein the second track member of each of the first swing portion and the second swing portion is connected to the frame, and the second bearing portion of each of the first swing portion and the second swing portion is separate from the frame.

2. The straight-curved guide device according to claim 1,
wherein the first track member includes:
a shaft member passing through the arm portion in the height direction of the rail; and
an annular member surrounding an outer peripheral surface of the shaft member,
wherein a first thread portion is formed on the outer peripheral surface of the shaft member,
wherein a second thread portion to be meshed with the first thread portion is formed on an inner peripheral surface of the annular member, and
wherein the first raceway surface is formed on an outer peripheral surface of the annular member.

3. The straight-curved guide device according to claim 1,
wherein the frame has an insertion hole into which the second track member is inserted, and
wherein the second track member has an outer peripheral surface being in contact with an entire wall surface of the insertion hole in a circumferential direction.

4. The straight-curved guide device according to claim 3,
wherein the second track member has a feed port for feeding the first rolling elements into the first rolling passage, which is formed so as to pass through the second track member in a radial direction of the second track member,
wherein the second track member includes a lid member configured to close the feed port,
wherein the lid member has a lid raceway surface being in contact with the first rolling elements and a lid outer surface being located on a side opposite to the lid raceway surface in the radial direction of the second track member, and
wherein the lid outer surface is in contact with the wall surface of the insertion hole.

5. The straight-curved guide device according to claim 1, further comprising fixing members configured to fix each of the first swing portion and the second swing portion to the frame,
wherein the frame has first fixing holes into which the fixing members are inserted, and
wherein the second track member has second fixing holes, which communicate with the first fixing holes and into which the fixing members are inserted.

6. The straight-curved guide device according to claim 1,
wherein the fourth track member passes through the arm portion in the height direction of the rail,
wherein the second bearing portion further includes an eccentric collar having a circular annular shape, which is inserted between a wall surface of a through hole of the arm portion, through which the fourth track member passes, and an outer peripheral surface of the fourth track member, and
wherein the eccentric collar has a shape with a radial thickness changing in a circumferential direction.

7. The straight-curved guide device according to claim 2,
wherein the frame has an insertion hole into which the second track member is inserted, and
wherein the second track member has an outer peripheral surface being in contact with an entire wall surface of the insertion hole in a circumferential direction.

8. The straight-curved guide device according to claim 7,
wherein the second track member has a feed port for feeding the first rolling elements into the first rolling passage, which is formed so as to pass through the second track member in a radial direction of the second track member,
wherein the second track member includes a lid member configured to close the feed port,
wherein the lid member has a lid raceway surface being in contact with the first rolling elements and a lid outer surface being located on a side opposite to the lid raceway surface in the radial direction of the second track member, and
wherein the lid outer surface is in contact with the wall surface of the insertion hole.

9. The straight-curved guide device according to claim 2, further comprising fixing members configured to fix each of the first swing portion and the second swing portion to the frame,
wherein the frame has first fixing holes into which the fixing members are inserted, and
wherein the second track member has second fixing holes, which communicate with the first fixing holes and into which the fixing members are inserted.

10. The straight-curved guide device according to claim 2,
wherein the fourth track member passes through the arm portion in the height direction of the rail,
wherein the second bearing portion further includes an eccentric collar having a circular annular shape, which is inserted between a wall surface of a through hole of the arm portion, through which the fourth track member passes, and an outer peripheral surface of the fourth track member, and
wherein the eccentric collar has a shape with a radial thickness changing in a circumferential direction.
